(19) United States
(12) Patent Application Publication
(10) Pub. No.: US 2005/0112825 A1
(43) Pub. Date: May 26, 2005

(54) Method for manufacturing a semiconductor device

(76) Inventor: Yoshikazu Kasuya, Sukata-shi (JP)

Correspondence Address: HARNESS, DICKEY & PIERCE, P.L.C., P.O. BOX 828, BLOOMFIELD HILLS, MI, 48303, US

(21) Appl. No.: 10/976,243

(22) Filed: Oct. 28, 2004

(30) Foreign Application Priority Data
Oct. 30, 2003 (JP) 2003-370441

(51) Int. Cl. H01L 21/336; H01L 21/76

(52) U.S. Cl. 438/279; 438/296

(57) ABSTRACT

A semiconductor device manufacturing method includes: forming a first isolation region for setting a high-voltage-proof transistor forming region in a semiconductor layer; forming a second isolation region for setting a low-voltage-driven transistor forming region in the semiconductor layer by shallow-trench-isolation processing; and forming an offset insulating layer for electric field relaxation of high-voltage-proof transistors in the semiconductor layer by local-oxidation-of-silicon processing. The second step including: forming a trench in the semiconductor layer; forming an insulating layer filling up the trench and covering the entire upper surface of the semiconductor layer; removing part of the exposed insulating layer with a mask covering the insulating layer above a the offset insulating layer forming region and the trench forming region; removing at least the insulating layer in the high-voltage-proof transistor forming region by chemical-mechanical-polishing; and removing the insulating layer in the offset insulating layer forming region.

### RELATED APPLICATIONS

This application claims priority to Japanese Patent Application No. 2003-370441 filed Oct. 30, 2003 which is hereby expressly incorporated by reference herein in its entirety.

### BACKGROUND

1. Technical Field

The present invention relates to a method for manufacturing a semiconductor device having a high-voltage-proof transistor and a low-voltage-driven transistor that are provided on the same semiconductor layer, and more particularly to a method for manufacturing a semiconductor device employing both local oxidation of silicon (LOCOS) and shallow trench isolation (STI) processes.

2. Related Art

A field-effect transistor having a LOCOS offset-structure has been proposed to withstand high voltages. The field-effect transistor having a LOCOS offset structure is a transistor having a LOCOS layer provided between a gate insulating layer and a drain region, and also having an offset impurity layer provided under the LOCOS layer. In manufacturing this type of field-effect transistor, a LOCOS layer for isolating elements and a LOCOS layer for the offset structure are formed in the same step.

As smaller and lighter configurations have been adopted for various types of electronic devices in recent years, there is a need for smaller integrated circuits (IC) embedded in these devices. As for electronic devices equipped with a liquid crystal display in particular, a technology for mounting a low-voltage-driven transistor for low-voltage operation and a high-voltage-proof transistor for high-voltage operation on the same substrate or chip so as to reduce the chip area of an IC for driving is in great demand. In order to meet this demand, a method for forming an isolation region has shifted from LOCOS to STI. In line with this trend, the formation of a LOCOS offset layer by STI has been proposed.

However, if a thick gate insulating layer for a high-voltage-proof transistor is formed on an offset insulating layer formed by STI, the gate insulating layer tends to become thin at the upper end of a trench insulating layer, thereby making it difficult to form the gate insulating layer with an even thickness. Therefore, a method for manufacturing a semiconductor device employing both LOCOS and STI processes has been proposed. In such a method, STI is used for achieving a small configuration for some areas (e.g., isolating areas) that are not adversely affected by the STI process for forming an insulating layer, while LOCOS is used for other areas that are adversely affected by the STI process.

The present invention aims to provide a method for manufacturing a semiconductor device having a high-voltage-proof transistor and a low-voltage-driven transistor that are provided on the same substrate, the method employing both LOCOS and STI processes to achieve a smaller configuration and improve reliability.

### SUMMARY

A method for manufacturing a semiconductor device of the present invention includes the following steps: (a) forming a first isolation region for setting a high-voltage-proof transistor forming region in a semiconductor layer; (b) forming a second isolation region for setting a low-voltage-driven transistor forming region in the semiconductor layer by a shallow-trench-isolation (STI) process; and (c) forming an offset insulating layer for electric field relaxation of a high-voltage-proof transistor in the semiconductor layer by a local-oxidation-of-silicon (LOCOS) process. The step (b) further includes the following steps: (b-1) forming a trench in the semiconductor layer; (b-2) forming an insulating layer so as to fill up the trench and cover an entire upper surface of the semiconductor layer; (b-3) removing part of the insulating layer that is exposed with the insulating layer placed above a region in which the offset insulating layer is formed and a region in which the trench is formed covered by a mask; (b-4) performing a chemical-mechanical-polishing (CMP) process so as to remove at least the insulating layer in the high-voltage-proof transistor forming region; and (b-5) removing the insulating layer in a region in which the offset insulating layer is formed.

The method for manufacturing a semiconductor device of the present invention employs both LOCOS and STI processes, and thereby desirably forms a LOCOS insulating layer and a trench insulating layer. The insulating layer formed by a LOCOS or semi-recessed LOCOS process is hereinafter called “LOCOS layer”, while the insulating layer formed by an STI process is called “trench insulating layer”.

In order to employ both LOCOS and STI processes, a method that forms a LOCOS layer and then forms a trench insulating layer has been used. This methods aims to avoid stress on the trench insulating layer that can cause defects when the trench insulating layer formed in advance is placed under thermal treatment for forming the LOCOS layer.

In general, a trench insulating layer is formed by embedding an insulating layer in a trench formed in a semiconductor layer. In order to embed this insulating layer, an insulating layer filling up a trench is provided on the entire surface of a semiconductor layer, and then unnecessary parts of the insulating layer are removed. In this CMP process, since the LOCOS layer in the surface of the semiconductor layer formed in advance swells above the surface of the semiconductor layer, the surface of the semiconductor layer has bumps that can prevent the CMP process from being desirably conducted. Therefore, in order to equalize a surface ratio of convex portions in the surface of the semiconductor layer, part of the insulating layer may be removed by using a mask that is inverted from the mask used for forming the trench prior to the CMP process. Using the inverted mask, however, can remove the entire surface of the insulating layer that is above the region in which the LOCOS layer is formed. Consequently, a comparatively large concave portion may be developed in the region in which the LOCOS layer is formed. If CMP is conducted here, even a stopper layer may be removed, and part of the insulating layer may remain on the stopper layer around a bump of the LOCOS layer.

In the step (b-3) of the method for manufacturing a semiconductor device according to the present invention, while a mask is placed on at least the region in which the offset insulating layer including the LOCOS layer is formed, part of the insulating layer is etched in order to equalize a surface ratio of convex portions in other regions. Therefore, it is possible to avoid over-etching of the stopper film in the region in which the offset insulating layer is formed through the CMP process. Moreover, by removing the insulating layer that is formed above the region in which the offset insulating layer is formed after the CMP process, it is possible to prevent the insulating layer from remaining on the stopper film.

In the method for manufacturing a semiconductor device of the present invention, forming a specific layer (layer B) above another specific layer (layer A) includes both of the following: (1) forming the layer B directly on the layer A, and (2) forming the layer B on the layer A with yet another layer therebetween.

Other aspects of the method for manufacturing a semiconductor device of the present embodiment are given below.

In one aspect of the present invention, the method for manufacturing a semiconductor device may further include the following step before the step (b-4): forming a protective film so as to cover at least the insulating layer placed above a region in which the offset insulating layer is formed. In this aspect, the protective film is formed so as to at least cover the insulating layer that is above the region in which the offset insulating layer is formed. Therefore, it is possible to more surely prevent the silicon nitride film from being removed in the CMP process in the step (b-4).

In another aspect of the present invention, the protective film may be a silicon nitride film in the method for manufacturing a semiconductor device.

In another aspect of the present invention, the insulating layer may be formed by a high-density-plasma chemical-vapor-deposition (HDP-CVD) process in the step (b-2) in the method for manufacturing a semiconductor device.

In yet another aspect of the present invention, the offset insulating layer may be formed by a semi-recessed LOCOS process in the method for manufacturing a semiconductor device.

In yet another aspect of the present invention, the first isolation region and the offset insulating layer may be formed in the same step in the method for manufacturing a semiconductor device.

### BRIEF DESCRIPTION OF THE DRAWINGS

FIG. 1 is a sectional view schematically showing a semiconductor device manufactured by a method for manufacturing a semiconductor device according to one embodiment of the present invention.

FIG. 2 is a sectional view schematically showing a step of the method for manufacturing a semiconductor device of the present embodiment.

FIG. 3 is a sectional view schematically showing a step of the method for manufacturing a semiconductor device of the present embodiment.

FIG. 4 is a sectional view schematically showing a step of the method for manufacturing a semiconductor device of the present embodiment.

FIG. 5 is a sectional view schematically showing a step of the method for manufacturing a semiconductor device of the present embodiment.

FIG. 6 is a sectional view schematically showing a step of the method for manufacturing a semiconductor device of the present embodiment.

FIG. 7 is a sectional view schematically showing a step of the method for manufacturing a semiconductor device of the present embodiment.

FIG. 8 is a sectional view schematically showing a step of the method for manufacturing a semiconductor device of the present embodiment.

FIG. 9 is a sectional view schematically showing a step of the method for manufacturing a semiconductor device of the present embodiment.

FIG. 10 is a sectional view schematically showing a step of the method for manufacturing a semiconductor device of the present embodiment.

FIG. 11 is a sectional view schematically showing a step of the method for manufacturing a semiconductor device of the present embodiment.

FIG. 12 is a sectional view schematically showing a step of the method for manufacturing a semiconductor device of the present embodiment.

FIG. 13 is a sectional view schematically showing a step of the method for manufacturing a semiconductor device of the present embodiment.

FIG. 14 is a sectional view schematically showing a step of the method for manufacturing a semiconductor device of the present embodiment.

FIG. 15 is a sectional view schematically showing a step of the method for manufacturing a semiconductor device of the present embodiment.

FIG. 16 is a sectional view schematically showing a step of the method for manufacturing a semiconductor device of the present embodiment.

FIG. 17 is a sectional view schematically showing a step of the method for manufacturing a semiconductor device of the present embodiment.

FIG. 18 is a sectional view schematically showing a step of the method for manufacturing a semiconductor device of the present embodiment.

FIG. 19 is a sectional view schematically showing a step of the method for manufacturing a semiconductor device of the present embodiment.

FIG. 20 is a sectional view schematically showing a step of the method for manufacturing a semiconductor device of the present embodiment.

FIG. 21 is a sectional view schematically showing a step of the method for manufacturing a semiconductor device of the present embodiment.

FIG. 22 is a sectional view schematically showing a step of the method for manufacturing a semiconductor device of the present embodiment.

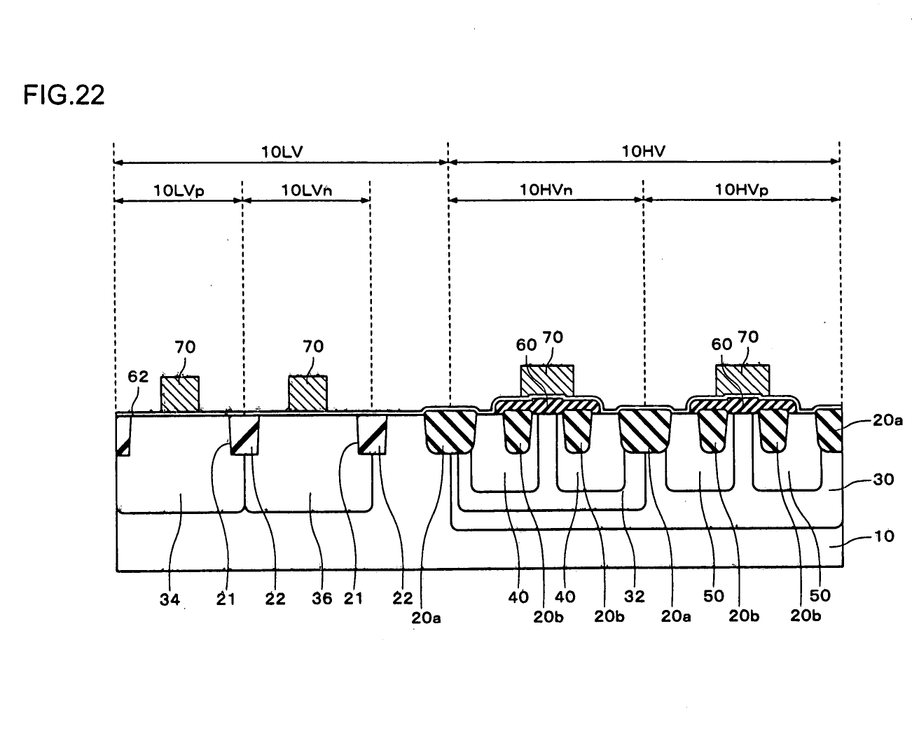

FIG. 23 is a sectional view schematically showing a step of a method for manufacturing a semiconductor device of as a modification.

### DETAILED DESCRIPTION

One embodiment of the present invention will now be described.

First, the structure of a semiconductor device manufactured by a method for manufacturing a semiconductor device according to the present embodiment will be described.

Semiconductor device

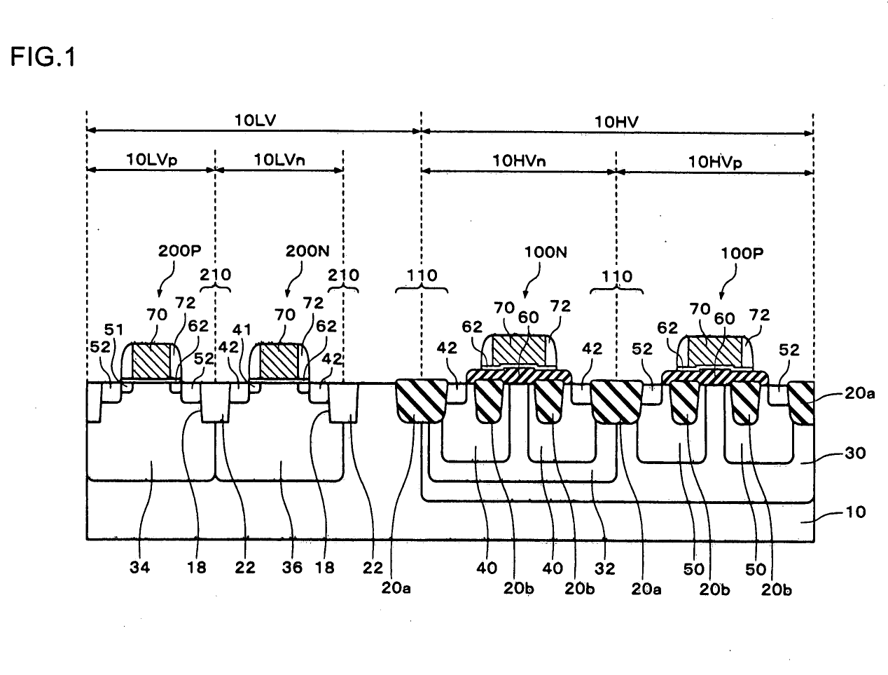

FIG. 1 is a sectional view schematically showing a semiconductor device manufactured by a method for manufacturing a semiconductor device according to the present embodiment. The semiconductor device manufactured by the method of the present embodiment includes high-voltage-proof transistors 100P and 100N (100P, N) and low-voltage-driven transistors 200P and 200N (200P, N) all of which are provided on a semiconductor substrate 10, which is a semiconductor layer. Provided in the semiconductor substrate 10 are a high-voltage-proof transistor region 10HV and a low-voltage-driven transistor region 10LV. The high-voltage-proof transistor region 10HV includes a P-channel high-voltage-proof transistor region 10HVp and an N-channel high-voltage-proof transistor region 10HVn. The low-voltage-driven transistor region 10LV includes a P-channel low-voltage-driven transistor region 10LVp and an N-channel low-voltage-driven transistor region 10LVn. The P-channel high-voltage-proof transistor 100P is formed in the P-channel high-voltage-proof transistor region 10HVp, while the N-channel high-voltage-proof transistor 100N is formed in the N-channel high-voltage-proof transistor region 10HVn. In the same manner, the P-channel low-voltage-driven transistor 200P is formed in the P-channel low-voltage-driven transistor region 10LVp, while the N-channel low-voltage-driven transistor 200N is formed in the N-channel low-voltage-driven transistor region 10LVn.

Therefore, the P-channel high-voltage-proof transistor 100P, the N-channel high-voltage-proof transistor 100N, the P-channel low-voltage-driven transistor 200P, and the N-channel low-voltage-driven transistor 200N are all formed on the same substrate (on the same chip). It is noted that four transistors are shown in FIG. 1 for the sake of convenience, and a plurality of each type of transistor is provided on the same substrate.

High-voltage-proof transistor region

First, the high-voltage-proof transistor region 10HV will be described. The high-voltage-proof transistor region 10HV includes the P-channel high-voltage-proof transistor region 10HVp and the N-channel high-voltage-proof transistor region 10HVn. Between neighboring high-voltage-proof transistor regions, a first isolation region 110 is provided. In other words, the first isolation region 110 is provided between the neighboring P-channel high-voltage-proof transistor 100P and N-channel high-voltage-proof transistor 100N. According to the method for manufacturing a semiconductor device of the present embodiment, the first isolation region 110 includes a LOCOS layer 20a.

The structure of the P-channel high-voltage-proof transistor 100P and the N-channel high-voltage-proof transistor 100N will now be described.

The P-channel high-voltage-proof transistor 100P includes a gate insulating layer 60, an offset insulating layer 20b having a semi-recessed LOCOS layer, a gate electrode 70, a P-type low-level impurity layer 50, a sidewall insulating layer 72, and a P-type high-level impurity layer 52.

The gate insulating layer 60 is formed above an N-type well 30 that is to be a channel region, above the offset insulating layer 20b, and above the semiconductor substrate 10 that is on both sides of the offset insulating layer 20b. The gate electrode 70 is formed at least above the gate insulating layer 60. The P-type low-level impurity layer 50 works as an offset region. The sidewall insulating layer 72 is formed on the side of the gate electrode 70. The P-type high-level impurity layer 52 is provided outside of the sidewall insulating layer 72. The P-type high-level impurity layer 52 works as a source region or drain region (hereinafter called a “source/drain region”).

The N-channel high-voltage-proof transistor 100N includes the gate insulating layer 60, the offset insulating layer 20b, the -gate electrode 70, an N-type low-level impurity layer 40, the sidewall insulating layer 72, and an N-type high-level impurity layer 42.

The gate insulating layer 60 is formed above a P-type well 32 that is to be a channel region, above the offset insulating layer 20b, and above the semiconductor substrate 10 that is on both sides of the offset insulating layer 20b. The gate electrode 70 is formed at least above the gate insulating layer 60. The N-type low-level impurity layer 40 works as an offset region. The sidewall insulating layer 72 is formed on the side of the gate electrode 70. The N-type high-level impurity layer 42 is provided outside of the sidewall insulating layer 72. The N-type high-level impurity layer 42 works as a source/drain region.

Low-voltage-driven transistor region

Now, the low-voltage-driven transistor region 10LV will be described. The low-voltage-driven transistor region 10LV includes the P-channel low-voltage-driven transistor region 10LVp and the N-channel low-voltage-driven transistor region 10LVn. Between neighboring low-voltage-driven transistor regions, a second isolation region 210 is provided. In other words, the second isolation region 210 is provided between the neighboring P-channel low-voltage-driven transistor 200P and N-channel low-voltage-driven transistor 200N. In the present embodiment, the second isolation region 210 includes a trench insulating layer 22.

The structure of each transistor will now be described.

The N-channel low-voltage-driven transistor 200N includes a gate insulating layer 62, the gate electrode 70, the sidewall insulating layer 72, an N-type low-level impurity layer 41, and the N-type high-level impurity layer 42.

The gate insulating layer 62 is provided above a P-type well 36 that is to be a channel region. The gate electrode 70 is formed on the gate insulating layer 62. The sidewall insulating layer 72 is formed on the side of the gate electrode 70. The N-type low-level impurity layer 41 and the N-type high-level impurity layer 42 make up a source/drain region having an LDD structure.

The P-channel low-voltage-driven transistor 200P includes the gate insulating layer 62, the gate electrode 70, the sidewall insulating layer 72, a P-type low-level impurity layer 51, and the P-type high-level impurity layer 52.

The gate insulating layer 62 is provided above an N-type well 34 that is to be a channel region. The gate electrode 70 is formed on the gate insulating layer 62. The sidewall insulating layer 72 is formed on the side of the gate electrode 70. The P-type low-level impurity layer 51 and the P-type high-level impurity layer 52 make up a source/drain region having an LDD structure.

Method for manufacturing a semiconductor device

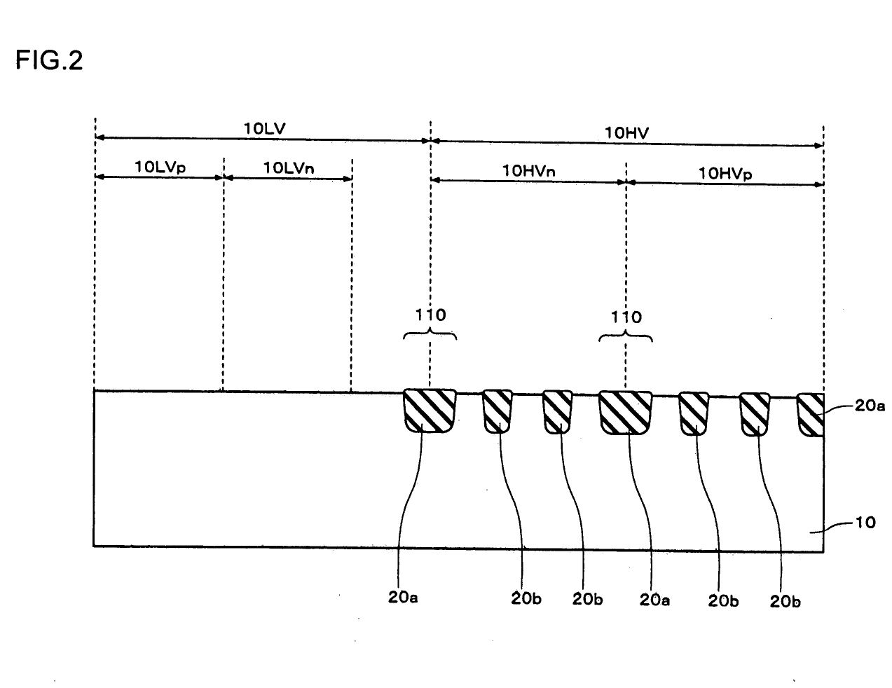

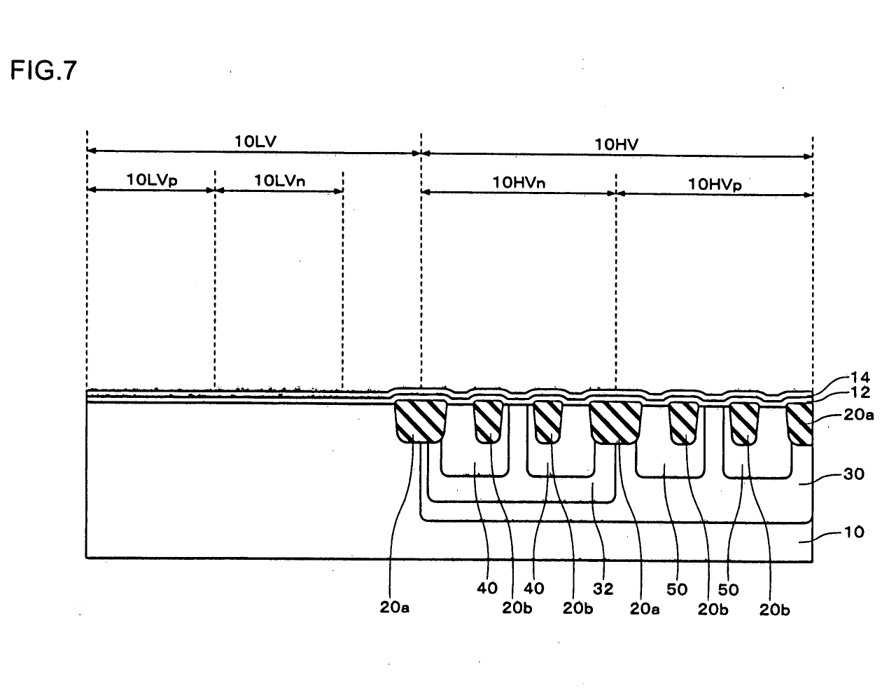

Referring now to FIGS. 2 through 21, the method for manufacturing a semiconductor device according to the present embodiment will be described. FIGS. 2 through 21 are sectional views schematically showing steps of the method for manufacturing a semiconductor device of the present embodiment.

(1) As shown in FIG. 2, the LOCOS layer 20a for element isolation and the offset insulating layer 20b for electric field relaxation are formed in the high-voltage-proof transistor forming region 10HV. An example of a method for forming the LOCOS layer 20a and the offset insulating layer 20b is given below.

First, a silicon nitride oxide layer is formed by chemical vapor deposition (CVD) on the semiconductor substrate 10. The thickness of the silicon nitride oxide layer is, for example, from 8 nm to 12 nm. Then, a silicon nitride layer is formed by CVD on the silicon nitride oxide layer. Next, on the silicon nitride layer a resist layer (not shown) having openings corresponding to the region in which the LOCOS layer 20a and the offset insulating layer 20b are formed is provided. Subsequently, the silicon nitride layer, the silicon nitride oxide layer, and the semiconductor substrate 10 are etched using the resist layer as a mask, so as to make concave portions corresponding to the region in which the LOCOS layer 20a and the offset insulating layer 20b are formed. The resist layer is then removed.

Then, a silicon oxide layer is formed on the exposed surface of the semiconductor substrate 10 by thermal oxidation. Thus, as shown in FIG. 2, the LOCOS layer 20a as the first isolation region 110 for setting a high-voltage-proof transistor forming region, and the offset insulating layer 20b of the high-voltage-proof transistors 100P, N are formed.

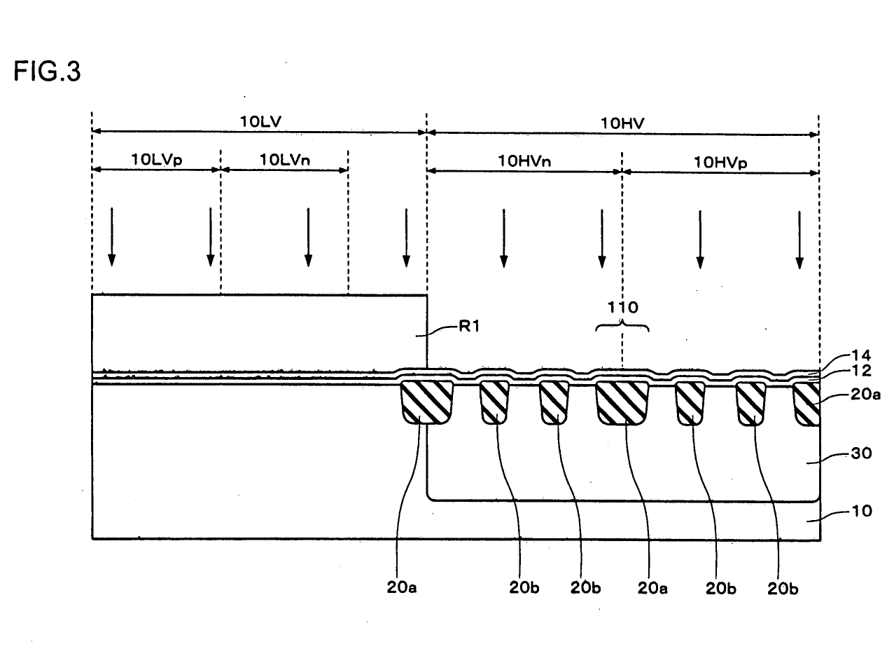

(2) The N-type well 30 is formed in the high-voltage-proof transistor region 10HV as shown in FIG. 3. A sacrifice oxide film 12 is formed on the entire surface of the semiconductor substrate 10. As the sacrifice oxide film 12, a silicon oxide film is provided, for example. Then, a silicon nitride film 14 is formed on the entire surface of the semiconductor substrate 10, and a resist layer R1 having a predetermined patter is also provided. Using the resist layer R1 as a mask, an N-type impurity such as phosphorus or arsenic is doped into the semiconductor substrate 10 one or more times. Subsequently the resist layer R1 is removed by ashing, for example. By diffusing the doped N-type impurity by thermal treatment, the N-type well 30 is formed in the semiconductor substrate 10.

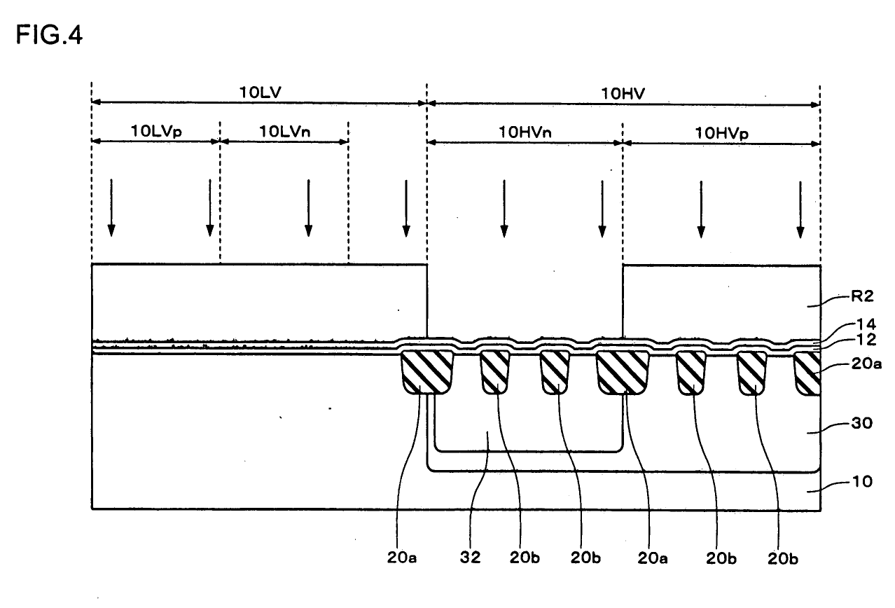

(3) The P-type well 32 is formed in the high-voltage-proof transistor region 10HV as shown in FIG. 4. First, a resist layer R2 having a predetermined pattern is formed. Using the resist layer R2 as a mask, an N-type impurity is doped into the semiconductor substrate 10 one or more times. The resist layer R2 is then removed by ashing. Subsequently, by diffusing the doped P-type impurity by thermal treatment, the P-type well 32 is formed. The thermal diffusion of the N-type impurity performed in the preceding step (2) and the thermal diffusion of the P-type impurity here may be performed all at once (simultaneously).

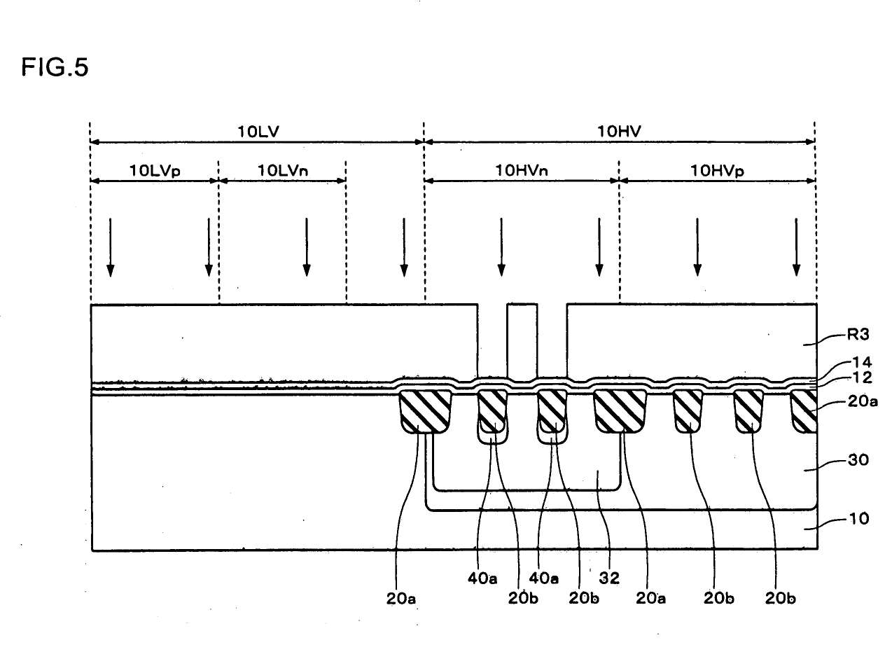

(4) An impurity layer for the offset region of the source/drain region is formed in the high-voltage-proof transistor region 10HV as shown in FIG. 5.

First, a resist layer R3 covering a predetermined region is formed. Then an impurity layer 40a is formed by doping a P-type impurity into the semiconductor substrate 10 by using the resist layer R3 as a mask. The resist layer R3 is then removed.

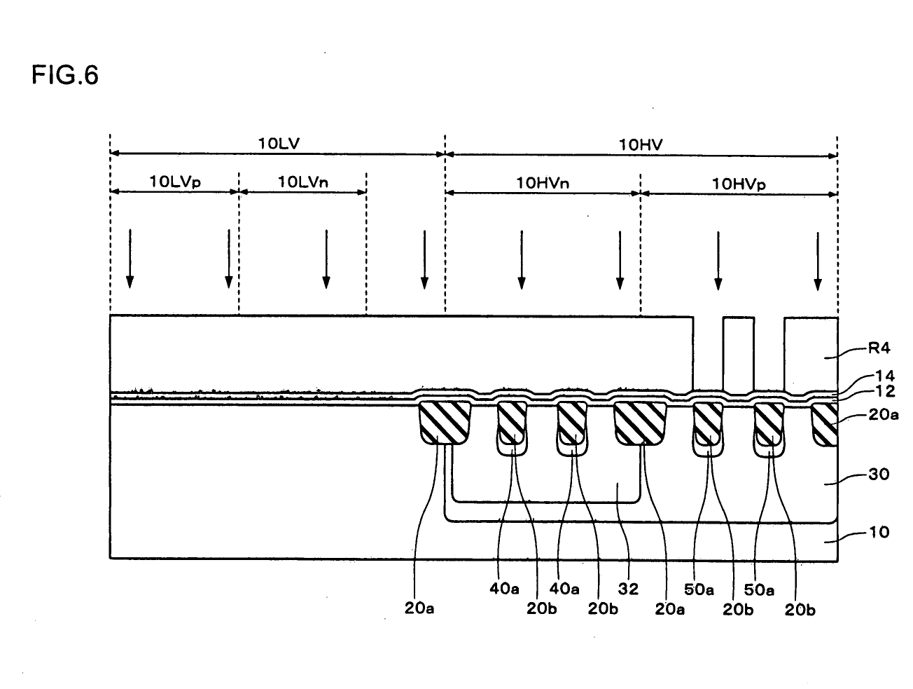

(5) A resist layer R4 covering a predetermined region is formed as shown in FIG. 6. Using the resist layer R4 as a mask, a P-type impurity is doped into the semiconductor substrate 10. This way an impurity layer 50a for the offset region of the source/drain region is formed in the P-channel high-voltage-proof transistor region 10HVp.

(6) A known method of thermal treatment is used to diffuse the impurity layers 40a, 50a, and thereby form the low-level impurity layers 40, 50 to be the offset region of the high-voltage-proof transistors 100P, N. The silicon nitride film 14 and the sacrifice oxide film 12 are then removed by a known method. By performing a thermal treatment for forming impurity layers for high-voltage-proof transistors before forming a trench insulating layer that will be described later, it is possible to prevent the trench insulating layer from being exposed to the thermal treatment for diffusing impurities. Therefore, it is possible to avoid nitriding of the surface of the trench insulating layer and crystal defects due to stress.

(7) An isolation region 210 (shown in FIG. 1) for setting the low-voltage-driven transistor forming region 10LV is formed by STI. The forming of the isolation region will now be described.

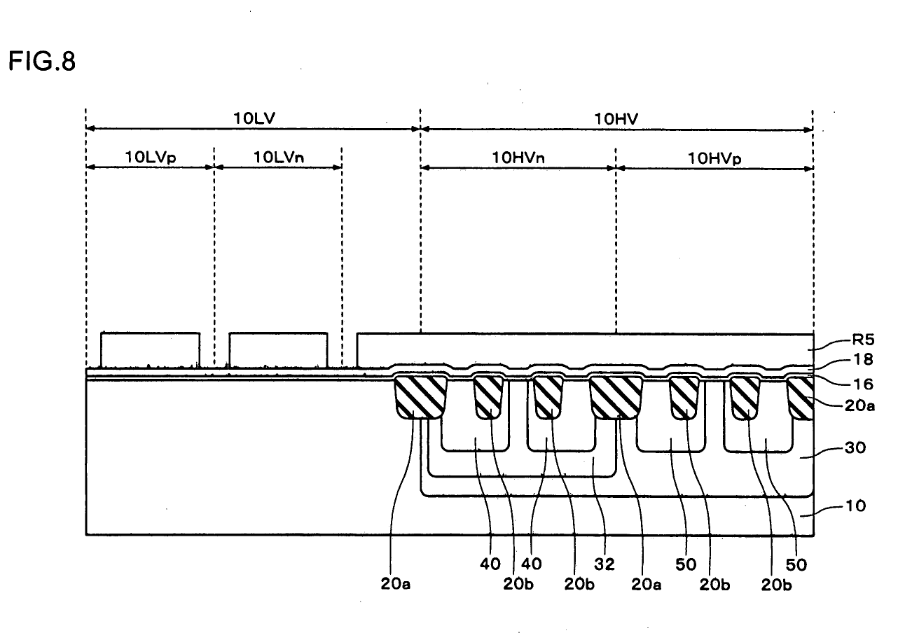

First, as shown in FIG. 8, silicon nitride films are formed on the entire surface of the semiconductor substrate 10 as a pad oxide film 16 and a stopper film 18. Then, a resist layer R5 as a mask layer with a predetermined pattern is formed on the stopper layer 18. The resist layer R5 has an opening corresponding to a region in which a trench is to be formed.

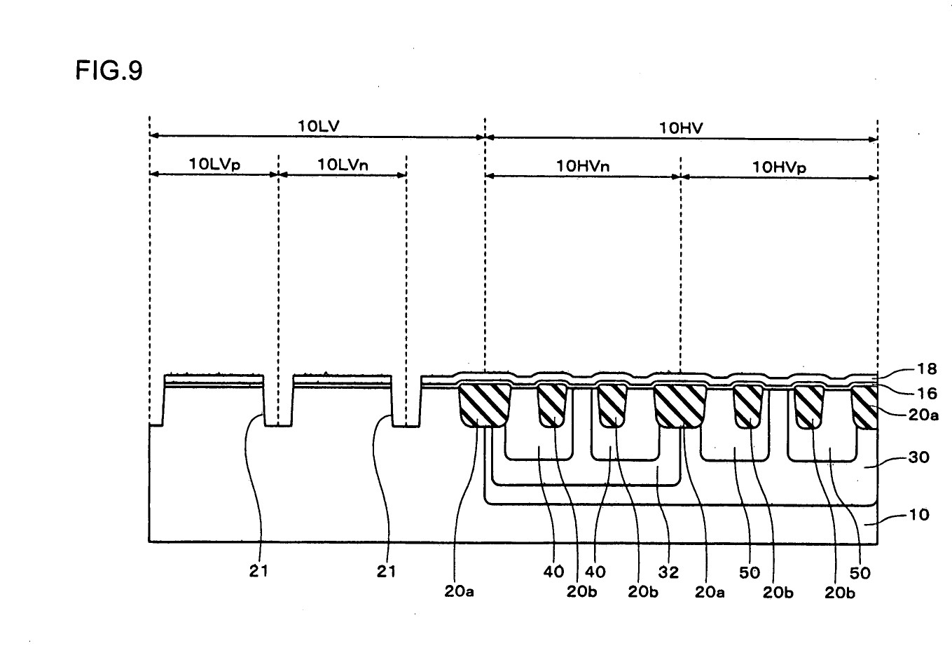

(8) Using the resist layer R5 (shown in FIG. 8) as a mask, the stopper film 18, the pad oxide film 16, and the semiconductor substrate 10 are etched. Accordingly, a trench 21 is formed in the semiconductor substrate 10 as shown in FIG. 9.

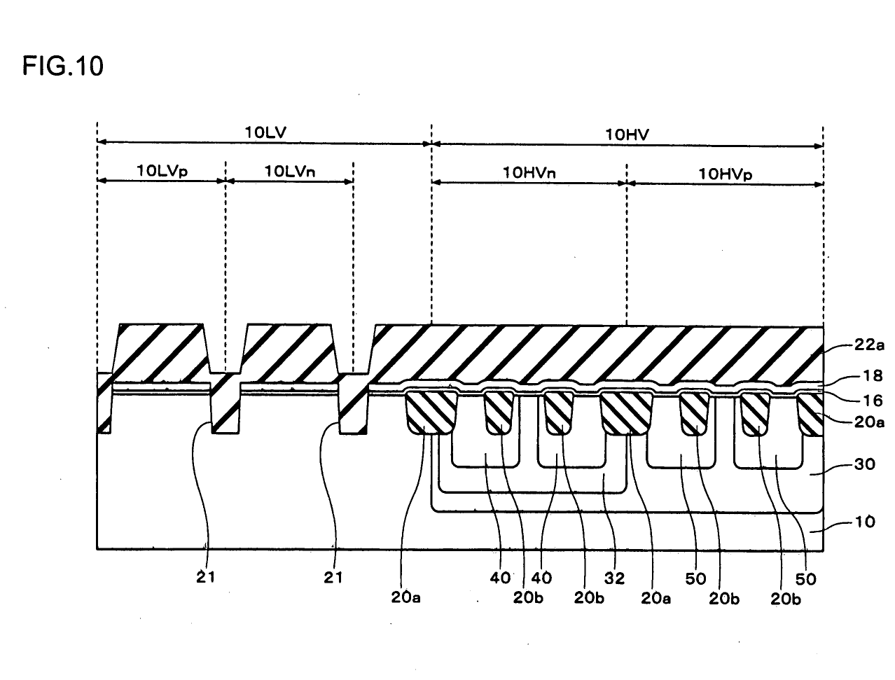

(9) Above the entire surface of the semiconductor substrate 10, an insulating layer 22a filling up the trench 21 is provided as shown in FIG. 10. Examples of the insulating layer 22a include a silicon oxide layer, and the layer can be formed by plasma CVD or HDP-CVD, for example.

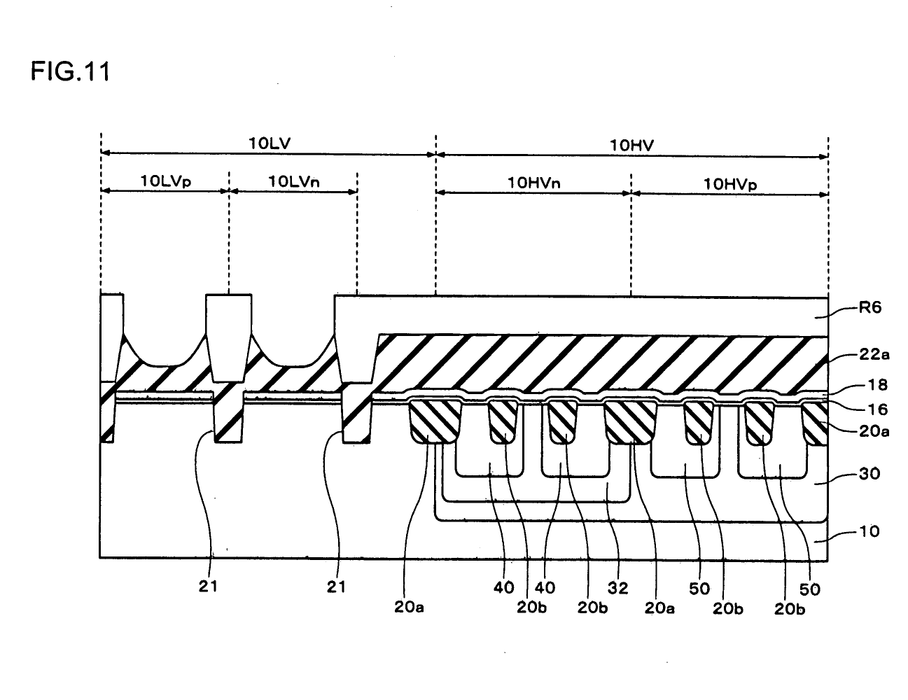

(10) In order to properly perform a CMP process that will be described later, part of the insulating layer 22a is etched so as to equalize surface ratios of convex portions in the surface of the semiconductor substrate 10 in the region (the high-voltage-proof transistor forming region 10HV, according to the present embodiment) in which the LOCOS layer 20a and the offset insulating layer 20b are formed. In this step, first a resist layer R6 is formed so as to cover the region in which the LOCOS layer 20a and the offset insulating layer 20b are formed, and the region in which the trench 21 is formed in the low-voltage-driven transistor forming region 10LV, as shown in FIG. 11. Next, part of the insulating layer 22a that is not covered by the resist layer R6 is etched. The resist layer R6 is then removed.

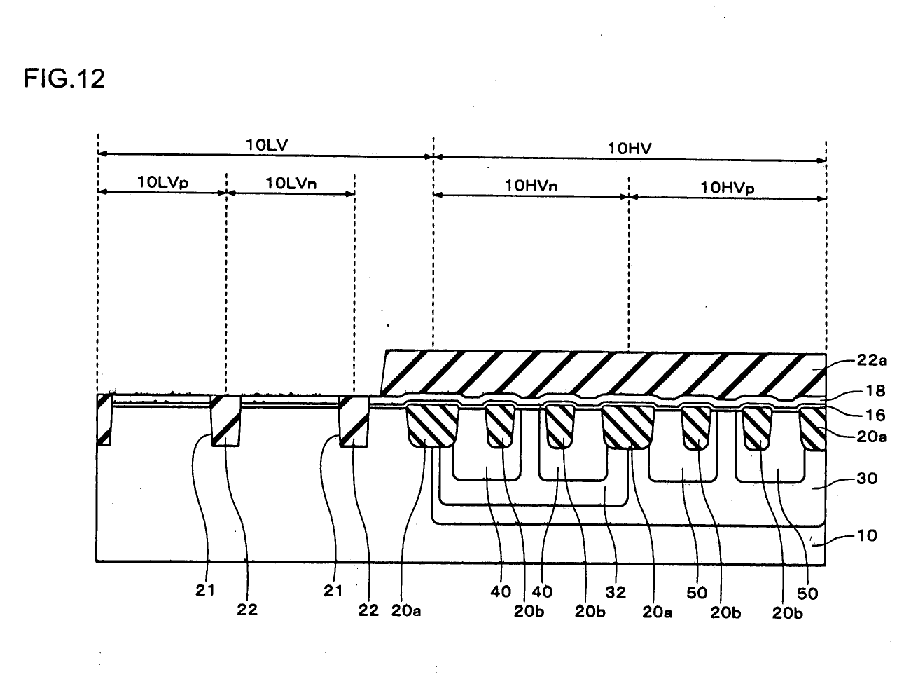

(11) The insulating layer 22a is removed by CMP in the region (the low-voltage-driven transistor forming region 10LV, according to the present embodiment) in which the trench 21 is formed until the stopper film 18 is exposed as shown in FIG. 12. Accordingly, the trench insulating layer 22 for setting the low-voltage-driven transistor forming region 10LV is formed.

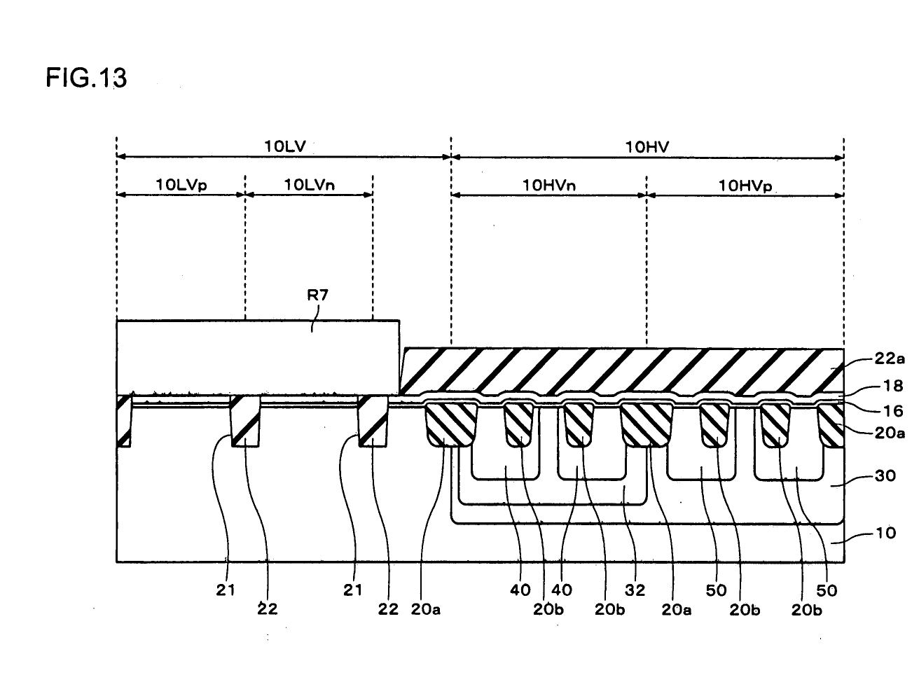

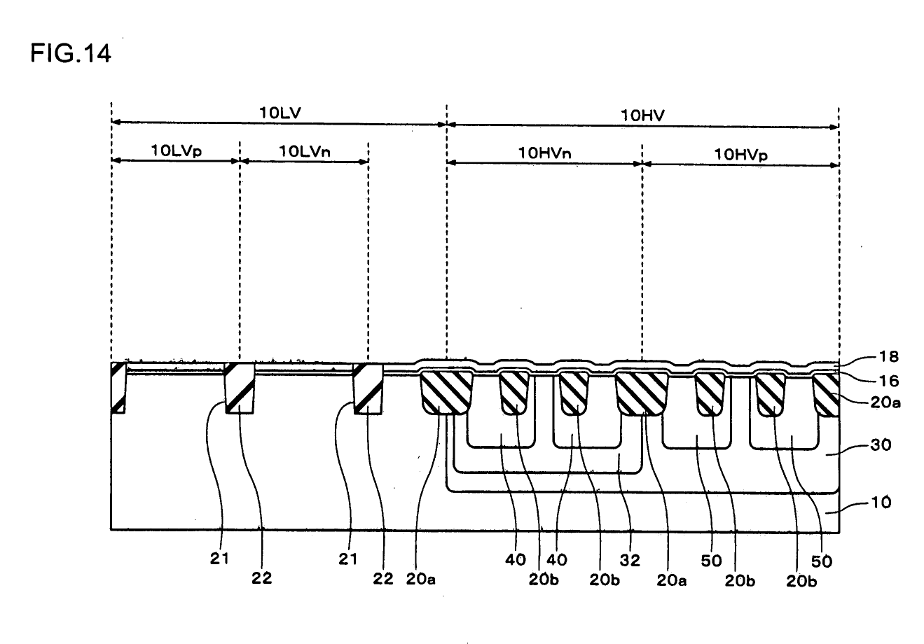

(12) The insulating layer 22a remaining in the region in which the LOCOS layer 20a and the offset insulating layer 20b are formed is removed until the silicon nitride film 18 is exposed as shown in FIG. 14. In this step, first a resist layer R7 is provided so as to cover the low-voltage-driven transistor forming region 10LV as shown in FIG. 13. The resist layer R7 is used for preventing the trench insulating layer 22 from being etched in a step for etching the insulating layer 22a remaining in the region in which the LOCOS layer 20a and the offset insulating layer 20b are formed. The same effect can be achieved by covering only the upper surface of the trench insulating layer 22. Alternatively, the insulating layer 22a remaining in the region in which the LOCOS layer 20a and the offset insulating layer 20b are formed can be removed so as to expose the silicon nitride film 18 without forming the resist layer R7. Subsequently, the insulating layer 22a remaining in the region in which the LOCOS layer 20a and the offset insulating layer 20b are formed is etched under the condition that a desirable etching selective ratio against the silicon nitride film 18 is satisfied so that the silicon nitride film 18 will not be etched. For example, this can be achieved by wet etching with buffered fluorinated acid. The resist layer R7 is then removed. The stopper film 18 and the pad oxide film 16 are then removed by a known method. In removing the pad oxide film 16, the upper surface of the trench insulating layer 22 is also removed.

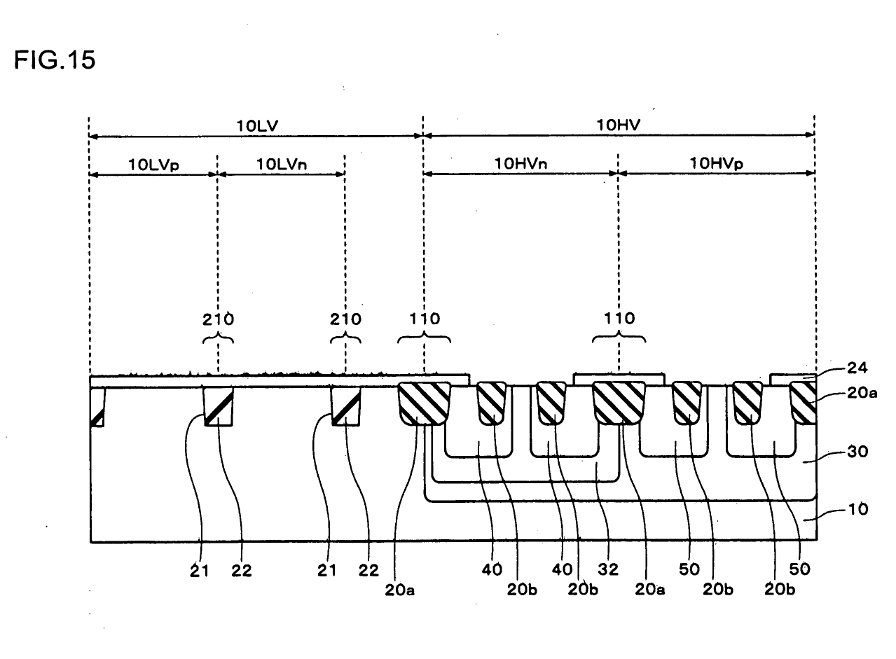

(13) A protective film 24 is formed to at least cover regions other than the region in which the gate insulating layer 60 of the high-voltage-proof transistors 100P, N is formed as shown in FIG. 15. As the protective film -24, a silicon nitride film is provided, for example. In order to form the protective film 24, first a silicon nitride film (not shown) is provided on the entire surface of the semiconductor substrate 10. Next, a resist layer (not shown) having an opening corresponding to the region in which the gate insulating layer 60 is to be formed in a later step is formed. The silicon nitride film is patterned by using this resist layer as a mask, and thereby forming the protective film 24.

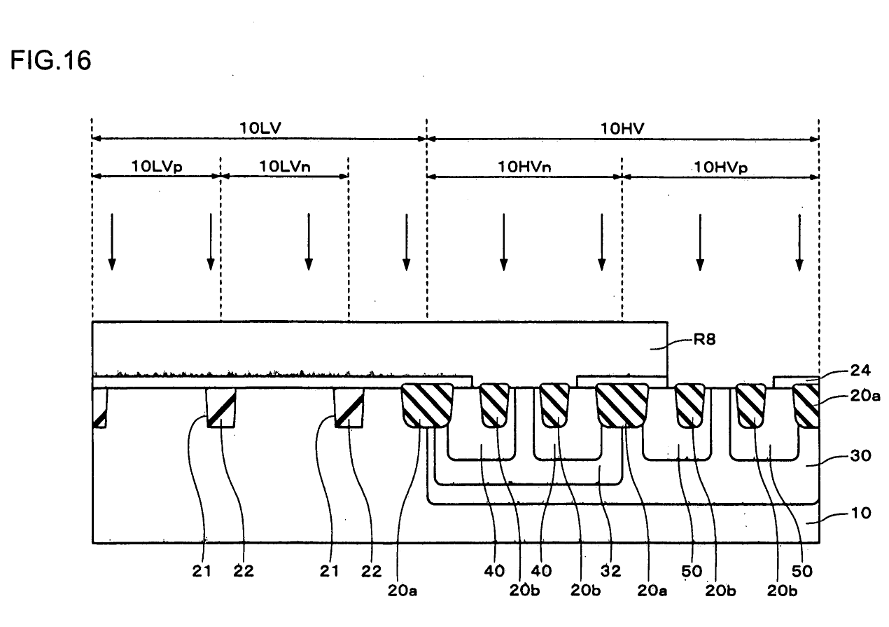

(14) Channel doping is performed in the high-voltage-proof transistor forming region 10HV. First, a resist layer R8 is provided so as to cover regions other than the P-channel high-voltage-proof transistor region 10HVp as shown in FIG. 16. By using the resist layer R8 as a mask, a P-type impurity such as boron is doped. The resist layer R8 is then removed by ashing.

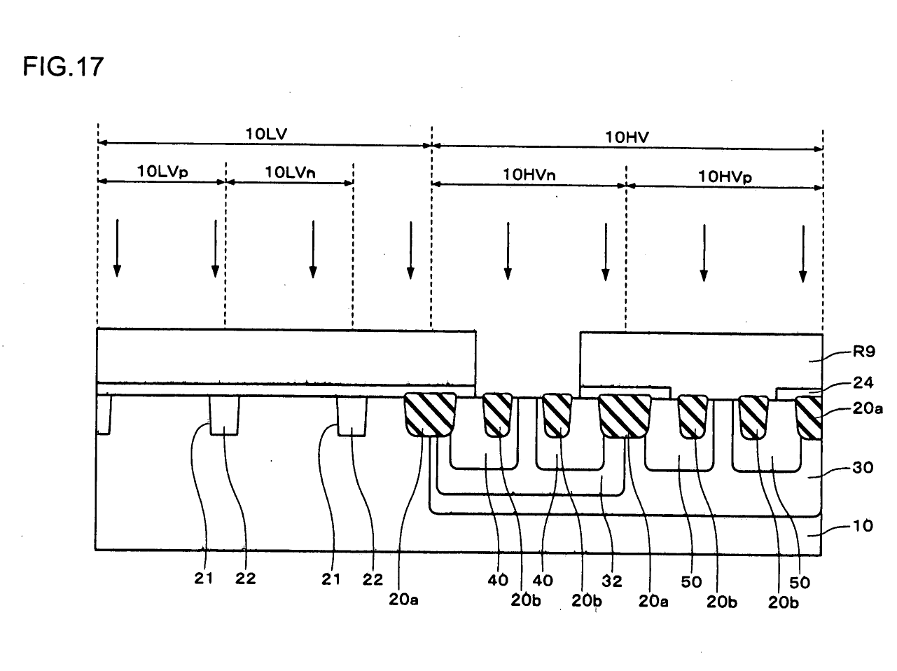

(15) A resist layer R9 is provided so as to cover regions other than the N-channel high-voltage-proof transistor region 10HVn as shown in FIG. 17. By using the resist layer R9 as a mask, an N-type impurity such as phosphorus is doped. The resist layer is then removed by ashing.

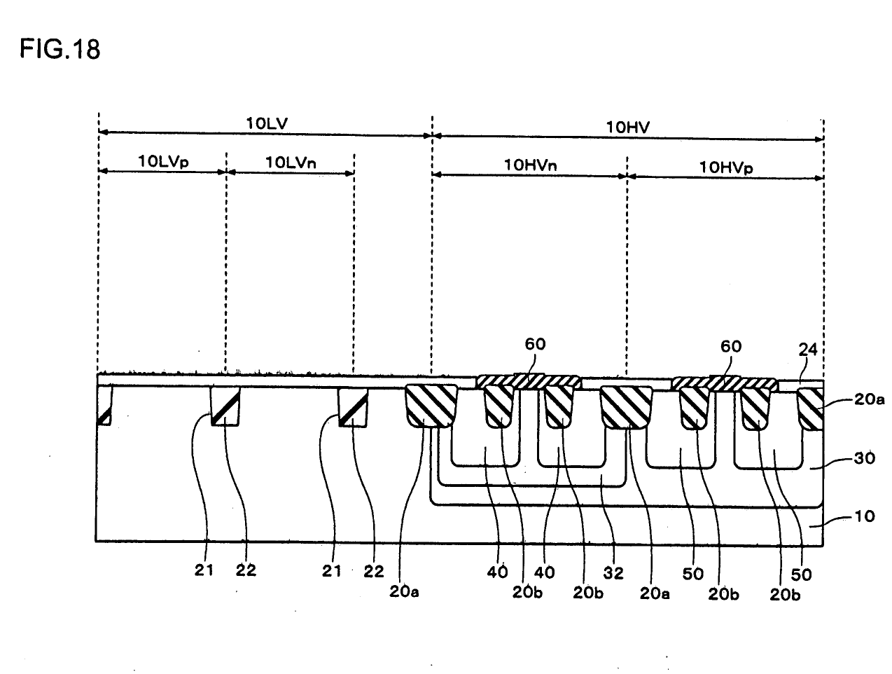

(16) The gate insulating layer 60 is formed in the high-voltage-proof transistor region 10HV as shown in FIG. 18. The gate insulating layer 60 may be formed by selective thermal oxidation. The thickness of the gate insulating layer 60 is 1600 Å, for example. The protective film 24 that is remaining is then removed.

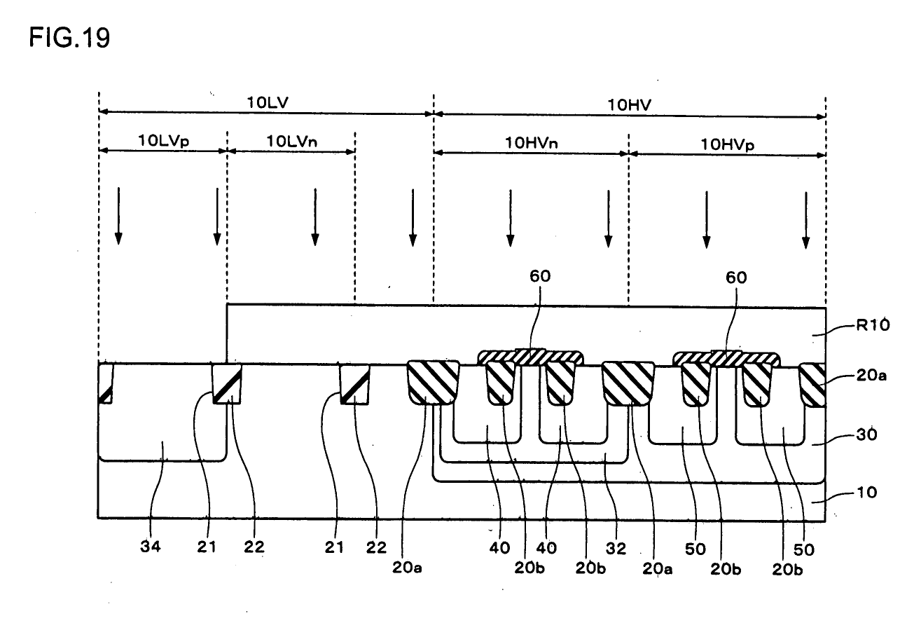

(17) A well is formed in the low-voltage-driven transistor region 10LV as shown in FIG. 19. First, a resist layer R10 is provided so as to cover regions other than the P-channel low-voltage-driven transistor region 10LVp. Using the resist layer R10 as a mask, an N-type impurity such as phosphorus, arsenic is doped one or more times so as to form the N-type well 34. The resist layer R10 is then removed.

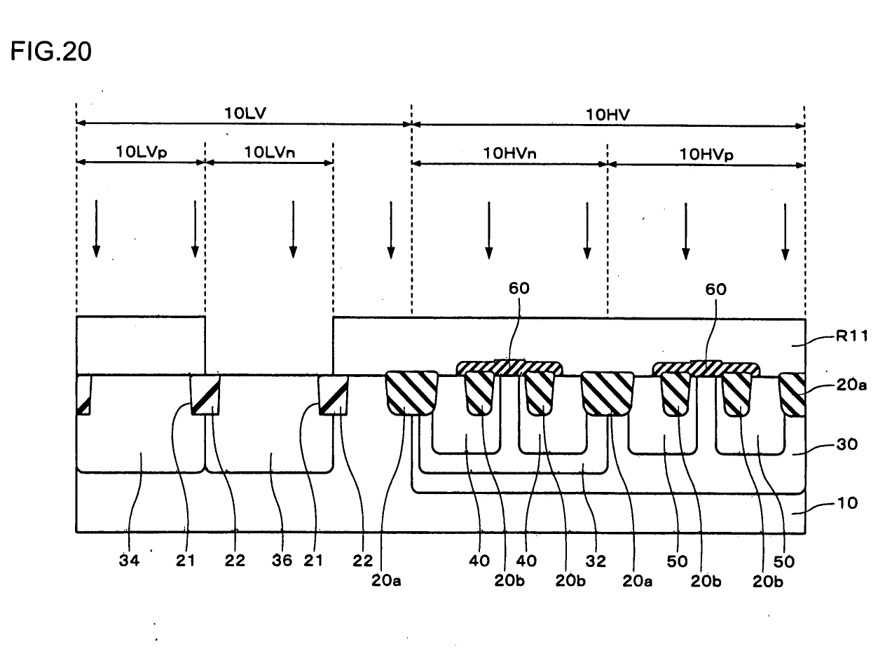

(18) A resist layer R11 is provided so as to cover regions other than the N-channel low-voltage-driven transistor region 10LVn as shown in FIG. 20. Using the resist layer R11 as a mask, a P-type impurity such as boron is doped one or more times so as to form the P-type well 36. The resist layer R11 is then removed. Channel doping may follow this step as necessary.

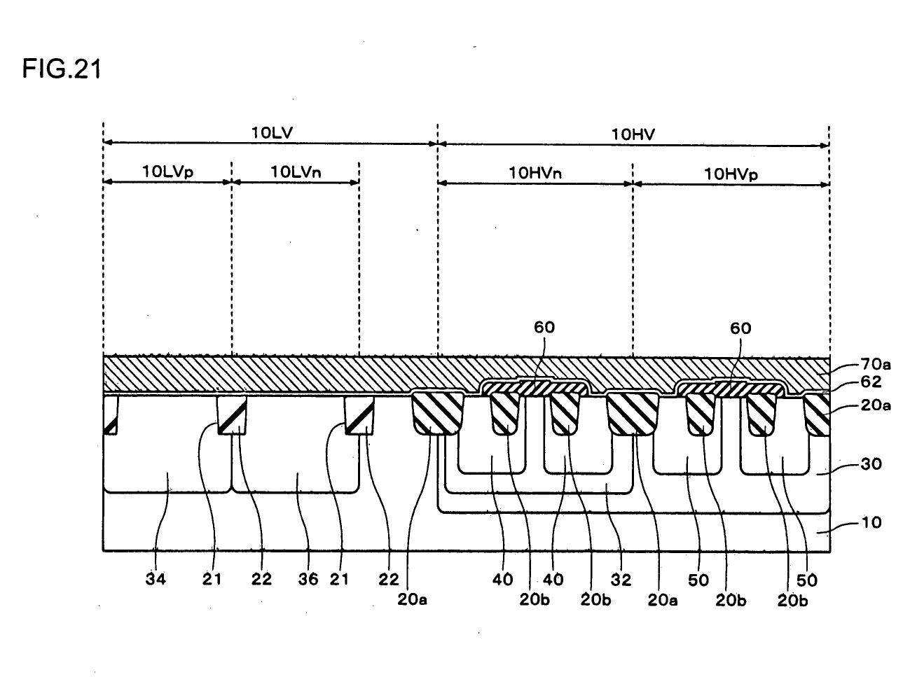

(19) The gate insulating layer 62 for the low-voltage-driven transistors 200P, N is formed as shown in FIG. 21. The gate insulating layer 42 may be formed by thermal oxidation, for example. The thickness of the gate insulating layer 62 is 45 Å, for example. The gate insulating layer 62 is also provided in the high-voltage-proof transistor region 10HV.

A conductive layer 70a is formed on the entire surface of the high-voltage-proof transistor region 10HV and the low-voltage-driven transistor region 10LV as shown in FIG. 21. As the conductive layer 70a, a polysilicon layer, for example, is provided. When using a polysilicon layer as the conductive layer 70a, an n-type impurity may be doped into the region in the conductive layer 70a corresponding to the gate electrode of the N-channel high-voltage-proof transistor 100N and the N-channel low-voltage-driven transistor 200N, in order to lower the resistance of the gate electrode.

(20) A resist layer (not shown) having a predetermined pattern is formed. The gate electrode 70 is formed by patterning the polysilicon layer by using the resist layer as a mask.

(21) The low-level impurity layers 41, 51 (shown in FIG. 1) for the transistors 200P, N, respectively, are formed in the low-voltage-driven transistor region 10LV. The low-level impurity layers 41, 51 are formed by forming a mask layer by a known lithography technique and doping a predetermined impurity.

Subsequently an insulating layer (not shown) is formed on the entire surface. The insulating layer is anisotropically etched, and thus the sidewall insulating layer 72 (shown in FIG. 1) is formed on the side of the gate electrode 70. Then, by doping a P-type impurity into a predetermined region in the P-channel high-voltage-proof transistor region 10HVp and the P-channel low-voltage-driven transistor region 10LVp, the P-type high-level impurity layer 52 to be a source/drain region is formed outside of the sidewall insulating layer 72 as shown in FIG. 1.

Then, by doping an N-type impurity into a predetermined region in the N-channel high-voltage-proof transistor region 10HVn and the N-channel low-voltage-driven transistor region 10LVn, the N-type high-level impurity layer 42 to be a source/drain region is formed.

Advantages of the method for manufacturing a semiconductor device according to the present embodiment will now be described.

The method for manufacturing a semiconductor device according to the present embodiment can provide a smaller semiconductor device, since the second isolation region 210 of the low-voltage-driven transistor forming region 10LV is formed by STI. The offset insulating layer 20b of the high-voltage-proof transistors 100P, N is formed by the semi-recessed LOCOS process, which is a kind of selective oxidation. Therefore, the upper end of the offset insulating layer 20b has a bird beak shape. This can prevent thinning of the gate insulating layer 60. Accordingly, the gate insulating layer 60 of the high-voltage-proof transistors 100P, N can be made evenly thick at the upper end of the offset insulating layer 20b as well. As a result, it is possible to achieve a smaller configuration and improve reliability in providing a semiconductor device.

The method for manufacturing a semiconductor device according to the present embodiment employs both LOCOS and STI processes, and thereby desirably forming LOCOS and STI layers.

In order to employ both LOCOS and STI processes, a method that forms a LOCOS layer and then forms a trench insulating layer has been used. This methods aims to avoid stress on the trench insulating layer that can cause crystal defects when the trench insulating layer formed in advance is placed under thermal treatment for forming the LOCOS layer.

In general, a trench insulating layer is formed by embedding an insulating layer in a trench formed in a semiconductor layer. In order to embed the insulating layer, an insulating layer filling up a trench is provided on the entire surface of a semiconductor layer, and then unnecessary parts of the insulating layer are removed. In this CMP process, since the LOCOS layer formed in advance swells above the surface of the semiconductor layer, the semiconductor layer has concave and convex surfaces that can prevent the CMP process from being desirably conducted. Therefore, in order to equalize a surface ratio of convex portions in the surface of the semiconductor layer, part of the insulating layer may be removed by using a mask that is inverted from the mask used for forming the trench prior to the CMP process. Using the inverted mask, however, can remove the entire surface of the insulating layer that is above the region in which the LOCOS layer is formed. Consequently, a comparatively large concave portion will be developed in the region in which the LOCOS layer is formed. If CMP is conducted here, even a silicon nitride film serving as a stopper layer above the LOCOS layer may be overetched and thus the LOCOS layer is possibly etched. Also, part of the insulating layer possibly remains on the stopper layer around a bump of the LOCOS layer.

In the step (10) of the method for manufacturing a semiconductor device according to the present embodiment, while a mask is placed on the region in which the LOCOS layer 20a and the offset insulating layer 20b are formed, part of the insulating layer is etched in order to equalize a surface ratio of convex portions in other regions. Therefore, it is possible to avoid the overetching of the stopper film 18 in the region in which the LOCOS layer 20a and the offset insulating layer 20b are formed through the CMP process. Moreover, by removing the insulating layer 22a that is formed above the region in which the LOCOS layer 20a and the offset insulating layer 20b are formed after the CMP process, it is possible to prevent the insulating layer 22a from remaining on the stopper film 18.

Modification

A modification of the method for manufacturing a semiconductor device according to the present embodiment will now be described.

The modification of the present embodiment differs from the above-mentioned method in the step (10). Differences from the above-mentioned method will be described below.

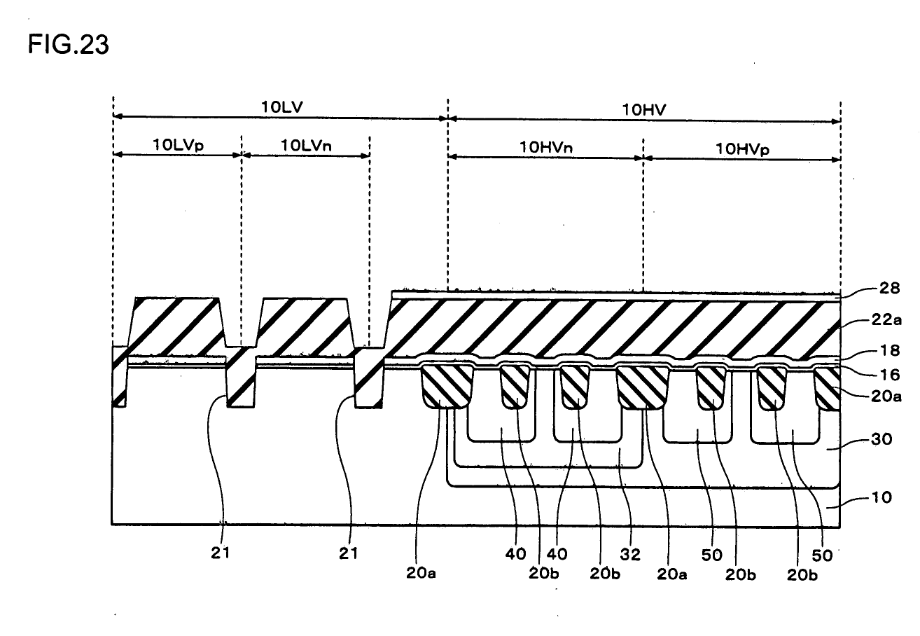

The steps (1) through (9) of the above-mentioned embodiment are taken so as to form the insulating layer 22a on the entire surface of the semiconductor substrate 10 as shown in FIG. 23. Then an insulating layer (not shown) that is to serve as a protective film is formed above the insulating layer 22a. The insulating layer is made of a material that has a desirable etching selective ratio against the insulating layer 22a. Examples of such a material include a silicon nitride film. Then, the insulating layer is patterned so as to form a cover film (protective film) 28 above the region in which the LOCOS layer 20a and the offset insulating layer 20b are formed. The patterning is carried out by general lithography and etching techniques. The thickness of the cover film 28 is preferably set so as to be removed by CMP in the following step (11). This is because, if the cover film 28 is too thick to be removed by CMP in the step (11), the cover film 28 remains after CMP, and thus the insulating layer on the LOCOS region will not be removed in the step (12).

The steps (11) through (21) of the above-mentioned embodiment follow this process. Thus a semiconductor device of the present modification is manufactured.

According to the present modification, the CMP process is carried out with the region in which the LOCOS layer 20a and the offset insulating layer 20b are formed covered by the cover film 28. Therefore, the insulating layer 22a surely remains in the region in which the LOCOS layer 20a and the offset insulating layer 20b are formed, and thereby more surely avoiding the overetching of the stopper film 18.

It should be noted that the invention is not limited to the above-mentioned embodiment, and can be modified within the spirit and scope of the present invention. While the semi-recessed LOCOS process is used for forming the offset insulating layer 20b in the above-mentioned embodiment, it can be substituted by the LOCOS process. Also, the first isolation region 110 that sets the high-voltage-proof transistor forming region 10HV may be formed by STI.

1. A method for manufacturing a semiconductor device, comprising:
(a) forming a first isolation region for setting a high-voltage-proof transistor forming region in a semiconductor layer;
(b) forming a second isolation region for setting a low-voltage-driven transistor forming region in the semiconductor layer by a shallow-trench-isolation process; and
(c) forming an offset insulating layer for electric field relaxation of a high-voltage-proof transistor in the semiconductor layer by a local-oxidation-of-silicon process;
the step (b) including:
(b-1) forming a trench in the semiconductor layer;
(b-2) forming an insulating layer so as to fill up the trench and cover an entire upper surface of the semiconductor layer;
(b-3) removing part of the insulating layer that is exposed with a mask covering:
the insulating layer placed above a region in which the offset insulating layer is formed; and
a region in which the trench is formed;
(b-4) performing a chemical-mechanical-polishing process so as to remove at least the insulating layer in the high-voltage-proof transistor forming region; and
(b-5) removing the insulating layer in a region in which the offset insulating layer is formed.

2. The method for manufacturing a semiconductor device according to claim 1, further comprising:
forming a protective film so as to cover at least the insulating layer placed above a region in which the offset insulating layer is formed prior to step (b-4).

3. The method for manufacturing a semiconductor device according to claim 2, wherein the protective film comprises a silicon nitride film.

4. The method for manufacturing a semiconductor device according to claim 1, wherein the insulating layer is formed by a high-density-plasma chemical-vapor-deposition process in step (b-2).

5. The method for manufacturing a semiconductor device according to claim 1, wherein the offset insulating layer is formed by a semi-recessed local-oxidation-of-silicon process.

6. The method for manufacturing a semiconductor device according to claim 1, wherein the first isolation region and the offset insulating layer are formed in a same step.
